(19) United States
(12) Patent Application Publication
(10) Pub. No.: US 2025/0372384 A1
(43) Pub. Date: Dec. 4, 2025

(54) SELF-ALIGNED GATE CUT

(71) Applicant: Intel Corporation, Santa Clara, CA (US)

(72) Inventors: Hwichan Jun, Portland, OR (US); Joon Goo Hong, Austin, TX (US); Changyok Park, Portland, OR (US); Sheng-Po Fang, Vancouver, WA (US)

(73) Assignee: Intel Corporation, Santa Clara, CA (US)

(21) Appl. No.: 18/733,511

(22) Filed: Jun. 4, 2024

(51) Int. Cl. H01L 21/28; H01L 21/8234; H01L 27/088; H01L 29/06; H01L 29/423; H01L 29/66; H01L 29/775; H01L 29/786

(52) U.S. Cl. CPC H01L 21/28123; H10D 30/014; H10D 30/031; H10D 30/43; H10D 30/6735; H10D 30/6757; H10D 62/121; H10D 64/017; H10D 84/0128; H10D 84/0135; H10D 84/0151; H10D 84/038; H10D 84/83

(57) ABSTRACT

Techniques are provided herein to form semiconductor devices that include one or more gate cuts that are self-aligned within the gate trench between adjacent devices. A semiconductor device includes a gate structure around or otherwise on a semiconductor region. The gate structure includes a gate dielectric and a gate electrode. The gate structure may be interrupted, for example, between two transistors with a gate cut that extends through at least a portion of the entire thickness of the gate structure and includes dielectric material to electrically isolate the portions of the gate structure on either side of the gate cut. A dielectric plug contacts a top surface of the gate cut to separate the gate structure on either side of the dielectric plug. The gate cut is self-aligned between the adjacent semiconductor devices such that it is substantially equidistant between the semiconductor devices along the gate trench.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures used to isolate adjacent transistors becomes challenging. Accordingly, there remain a number of non-trivial challenges with respect to forming semiconductor devices.

### BRIEF DESCRIPTION OF THE DRAWINGS

FIGS. 1A and 1B are cross-sectional and plan views, respectively, of some semiconductor devices that have self-aligned gate cuts within the gate trench between the devices, in accordance with an embodiment of the present disclosure.

FIGS. 2A and 2B are cross-sectional and plan views that illustrate a first stage in an example process for forming semiconductor devices that have self-aligned gate cuts confined within the gate trench between the devices, in accordance with some embodiments of the present disclosure.

FIGS. 3A and 3B are cross-sectional and plan views that illustrate another stage in the example process for forming semiconductor devices that have self-aligned gate cuts confined within the gate trench between the devices, in accordance with some embodiments of the present disclosure.

FIGS. 4A and 4B are cross-sectional and plan views that illustrate another stage in the example process for forming semiconductor devices that have self-aligned gate cuts confined within the gate trench between the devices, in accordance with some embodiments of the present disclosure.

FIGS. 5A and 5B are cross-sectional and plan views that illustrate another stage in the example process for forming semiconductor devices that have self-aligned gate cuts confined within the gate trench between the devices, in accordance with some embodiments of the present disclosure.

FIGS. 6A and 6B are cross-sectional and plan views that illustrate another stage in the example process for forming semiconductor devices that have self-aligned gate cuts confined within the gate trench between the devices, in accordance with some embodiments of the present disclosure.

FIGS. 7A and 7B are cross-sectional and plan views that illustrate another stage in the example process for forming semiconductor devices that have self-aligned gate cuts confined within the gate trench between the devices, in accordance with some embodiments of the present disclosure.

FIGS. 8A and 8B are cross-sectional and plan views that illustrate another stage in the example process for forming semiconductor devices that have self-aligned gate cuts confined within the gate trench between the devices, in accordance with some embodiments of the present disclosure.

FIGS. 9A and 9B are cross-sectional and plan views that illustrate another stage in the example process for forming semiconductor devices that have self-aligned gate cuts confined within the gate trench between the devices, in accordance with some embodiments of the present disclosure.

FIGS. 10A and 10B are cross-sectional and plan views that illustrate another stage in the example process for forming semiconductor devices that have self-aligned gate cuts confined within the gate trench between the devices, in accordance with some embodiments of the present disclosure.

FIGS. 11A and 11B are cross-sectional and plan views that illustrate another stage in the example process for forming semiconductor devices that have self-aligned gate cuts confined within the gate trench between the devices, in accordance with some embodiments of the present disclosure.

FIGS. 12A and 12B are cross-sectional and plan views that illustrate another stage in the example process for forming semiconductor devices that have self-aligned gate cuts confined within the gate trench between the devices, in accordance with some embodiments of the present disclosure.

FIGS. 13A and 13B are cross-sectional and plan views that illustrate another stage in the example process for forming semiconductor devices that have self-aligned gate cuts confined within the gate trench between the devices, in accordance with some embodiments of the present disclosure.

FIGS. 14A and 14B are cross-sectional and plan views that illustrate another stage in the example process for forming semiconductor devices that have self-aligned gate cuts confined within the gate trench between the devices, in accordance with some embodiments of the present disclosure.

FIGS. 15A and 15B are cross-sectional and plan views that illustrate another stage in the example process for forming semiconductor devices that have self-aligned gate cuts confined within the gate trench between the devices, in accordance with some embodiments of the present disclosure.

FIGS. 16A and 16B are cross-sectional and plan views that illustrate another stage in the example process for forming semiconductor devices that have self-aligned gate cuts confined within the gate trench between the devices, in accordance with some embodiments of the present disclosure.

FIG. 17 is a cross-sectional view that illustrates a self-aligned gate cut confined within the gate trench between forksheet devices, in accordance with some embodiments of the present disclosure.

FIG. 18 illustrates a cross-sectional view of a chip package containing one or more semiconductor dies, in accordance with some embodiments of the present disclosure.

FIG. 19 is a flowchart of a fabrication process for semiconductor devices that have a self-aligned gate cut confined within the gate trench between the devices, in accordance with an embodiment of the present disclosure.

FIG. 20 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include one or more gate cuts that are self-aligned within the gate trench between adjacent devices. The techniques can be used in any number of integrated circuit applications and are particularly useful with respect to device layer transistors, such as finFETs or gate-all-around transistors (e.g., ribbonFETs and nanowire FETs) or forksheet transistors (e.g., nanosheet FETs). In an example, a semiconductor device includes a gate structure around or otherwise on a semiconductor region (also referred to as a channel region). The semiconductor region can be, for example, a fin of semiconductor material that extends from a source region to a drain region, or one or more nanowires, nanoribbons, or nanosheets of semiconductor material that extend from a source region to a drain region. The gate structure includes a gate dielectric (e.g., high-k gate dielectric material) and a gate electrode (e.g., conductive material such as workfunction material and/or gate fill metal). The gate structure may be interrupted, for example, between two transistors with a gate cut that extends through at least a portion of the entire thickness of the gate structure and includes dielectric material to electrically isolate the portions of the gate structure on either side of the gate cut. A dielectric plug contacts a top surface of the gate cut to separate the gate structure on either side of the dielectric plug. In an example, the gate cut is confined within the gate trench such that it does not extend beyond the walls of the gate trench as defined by gate spacer structures. In some examples, the gate cut is self-aligned between the adjacent semiconductor devices such that a distance from a first side of the gate cut to a first semiconductor device adjacent to the first side of the gate cut is substantially the same (e.g., within 0 to 20 angstroms) as a distance from an opposite second side of the gate cut to a second semiconductor device adjacent to the second side of the gate cut. Numerous configurations and variations will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Example structures like gate cuts are used in integrated circuit design to isolate gate structures from one another. Such gate cuts may be formed in various ways, but there are drawbacks to existing techniques for forming gate cuts. For example, gate cuts formed before the fabrication of the gate structures can suffer from uneven heights across multiple devices on a substrate while gate cuts formed by etching trenches through multiple different materials can have a detrimental impact on the formation of other conductive features, such as source or drain contacts, which may cause poor yield. Alignment error can also cause gate cuts at cell boundaries to be misaligned, which causes variation between the performance of the devices at the boundary.

Thus, and in accordance with an embodiment of the present disclosure, techniques are provided herein to form self-aligned gate cuts between devices (e.g., at a cell boundary) within the gate trench. The gate cuts may be formed prior to gate metallization, but after the formation of the gate dielectric within the gate trench. The gate cuts may be self-aligned between any types of transistor devices, such as finFETs, gate-all-around (GAA) devices, and forksheet devices. In the case of forksheet devices, the self-aligned gate cuts may be formed at a different time than the dielectric spine between the nanosheet devices. According to some embodiments, a sacrificial material is deposited over adjacent semiconductor devices within the gate trench following the formation of a gate dielectric over the semiconductor material of the semiconductor devices, leaving a space within the gate trench between the devices. That space generally defines the location of the gate cut and has a controllable width dependent on the thickness of the deposited sacrificial material. A portion of the sacrificial material along the bottom of the gate trench between the devices is etched away to form a recess, and a dielectric material is formed within the space between the devices and within the recess. Upon removal of the sacrificial material, the dielectric material remains as a gate cut within the gate trench between the two devices and is self-aligned between the two devices, according to some embodiments. Following the formation of a gate electrode on the gate dielectric, a portion of the gate electrode over the gate cut is removed and a dielectric plug is formed in its place to ensure complete separation of the gate structures on either side of the self-aligned gate cut.

According to an embodiment, an integrated circuit includes a first semiconductor device and a second semiconductor device. The first semiconductor device has a first semiconductor region extending in a first direction from a first source or drain region, and a first gate structure extending in a second direction over the first semiconductor region with the second direction being different than the first direction. The second semiconductor device has a second semiconductor region extending in the first direction from a second source or drain region, and a second gate structure extending in the second direction over the second semiconductor region. Spacer structures are on sidewalls of the first and second gate structures and extend along the second direction with the first and second gate structures, and a gate cut is between the first and second semiconductor devices and separates the first gate structure from the second gate structure along the second direction. A dielectric plug is on the top surface of the gate cut. The gate cut extends along a third direction through at least a portion of an entire height of the first and second gate structures. A top surface of the gate cut is below a top surface of the spacer structures. The dielectric plug also separates the first gate structure from the second gate structure along the second direction.

According to another embodiment, an integrated circuit includes a first semiconductor device and a second semiconductor device. The first semiconductor device has a first semiconductor region extending in a first direction from a first source or drain region, and a first gate structure extending in a second direction over the first semiconductor region with the second direction being different than the first direction. The second semiconductor device has a second semiconductor region extending in the first direction from a second source or drain region, and a second gate structure extending in the second direction over the second semiconductor region. Also, spacer structures are on sidewalls of the first and second gate structures and extend along the second direction with the first and second gate structures, and a gate cut is between the first and second semiconductor devices and separating the first gate structure from the second gate structure along the second direction. The gate cut extends along a third direction through at least a portion of an entire height of the first and second gate structures. The gate cut includes a first section directly contacting a first spacer structure of the spacer structures, a second section directly contacting a second spacer structure of the spacer structures, and a third section between the first and second sections. The third section extends beyond the first and second sections along the second direction.

According to another embodiment, a method of forming an integrated circuit includes: forming at least two adjacent fins comprising semiconductor material, the fins extending above a substrate and each extending parallel to one another in a first direction; forming a sacrificial gate extending over the semiconductor material in a second direction different from the first direction; forming spacer structures on sidewalls of the sacrificial gate; removing the sacrificial gate; forming a gate dielectric on the semiconductor material of each of the adjacent fins; forming a sacrificial structure over the adjacent fins; forming a masking material over the sacrificial structure between the spacer structures; etching a trench through the masking material between the adjacent fins, such that a portion of the sacrificial structure is exposed at a bottom of the trench; removing a portion of the sacrificial structure within the trench to form a recess; removing the masking material and forming a dielectric fill between the adjacent fins and within the recess; removing the sacrificial structure; forming a gate electrode over the gate dielectric on the semiconductor material of each of the adjacent fins, wherein a portion of the gate electrode extends over a top surface of the dielectric fill; and forming a dielectric plug through the portion of the gate electrode such that the dielectric plug contacts the top surface of the dielectric fill.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may be used to detect the presence of a gate cut between devices that does not extend outside of the gate trench (e.g., remains confined within the spacer structures) and is substantially equidistant (e.g., within 1-2 nm) between the adjacent semiconductor devices. In some examples, such tools may also be used to show that the gate dielectric around the semiconductor regions may abut the gate cut but does not extend up the sidewalls of the gate cut. Furthermore, a dielectric plug will be visible extending above a top surface of the gate cut to separate a top portion of the gate structures from one another. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

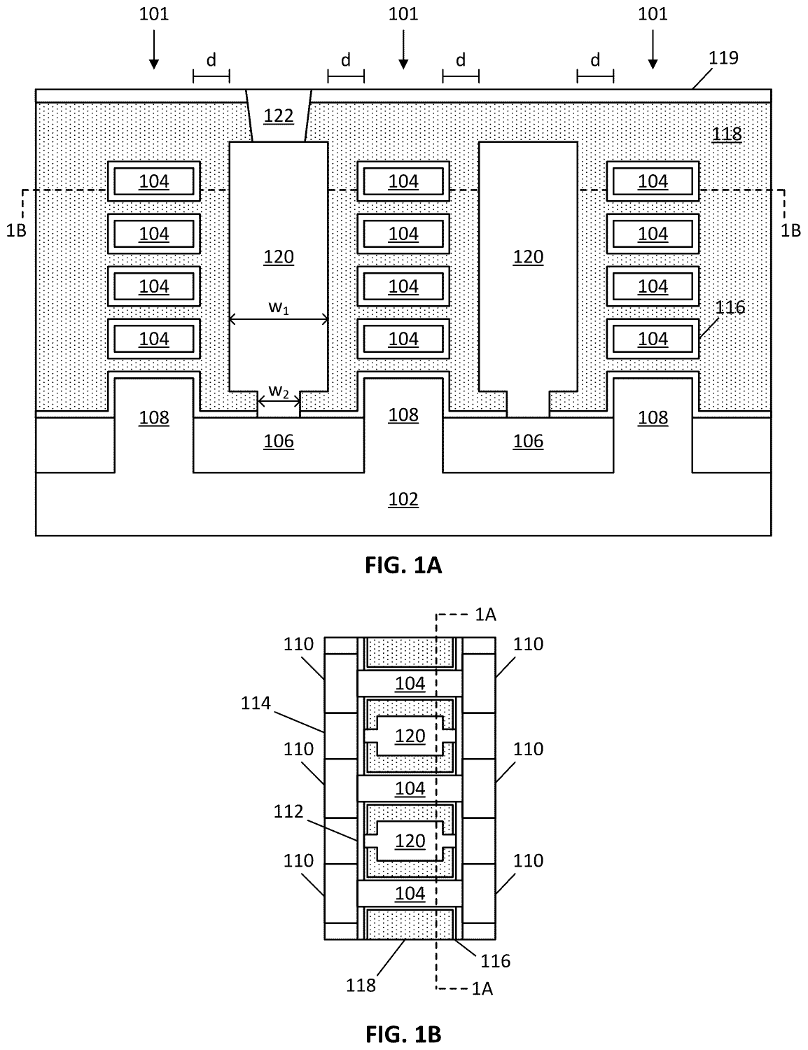

FIG. 1A is a cross-sectional view taken across several semiconductor devices 101, according to an embodiment of the present disclosure. FIG. 1B is a top-down cross-section view of the semiconductor devices 101 taken across the dashed line 1B-1B depicted in FIG. 1A, and FIG. 1A illustrates the cross-section taken across the dashed line 1A-1A depicted in FIG. 1B. It should be noted that some of the material layers (such as gate cap 119) are not visible in the top-down view of FIG. 1B, given the location of the depicted cross-section. Each of semiconductor devices 101 may be non-planar metal oxide semiconductor (MOS) transistors, such as tri-gate (e.g., finFET), gate-all-around (GAA), or forksheet transistors, although other transistor topologies and types could also benefit from the gate cut techniques and structures provided herein. The illustrated example embodiments herein use the GAA structure. Semiconductor devices 101 represent a portion of an integrated circuit that may contain any number of similar semiconductor devices.

As can be seen, semiconductor devices 101 are formed over a substrate 102. Any number of semiconductor devices can be formed over substrate 102, but three are shown here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some example embodiments, a lower portion of (or all of) substrate 102 is removed and replaced with one or more backside interconnect layers to form backside signal and power routing.

Each of semiconductor devices 101 includes one or more nanoribbons 104 that extend parallel to one another along a direction between a source region and a drain region (e.g., a first direction into and out of the page in the cross-section view of FIG. 1A). Nanoribbons 104 are one example of semiconductor regions or semiconductor bodies that extend between source and drain regions. The term nanoribbon may also encompass other similar shapes such as nanowires or nanosheets. The semiconductor material of nanoribbons 104 may be formed from substrate 102. In some embodiments, semiconductor devices 101 may each include semiconductor regions in the shape of fins that can be, for example, native to substrate 102 (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of the illustrated nanoribbons 104 during a gate forming process where one type of the alternating layers is selectively etched away so as to liberate the other type of alternating layers within the channel region, so that a gate-all-around (GAA) or forksheet process can then be carried out. Again, the alternating layers can be blanket deposited and then etched into fins or deposited into fin-shaped trenches, according to some examples.

As can further be seen, adjacent semiconductor devices are separated by a dielectric layer 106 that may include silicon dioxide. Dielectric layer 106 provides shallow trench isolation (STI) between any adjacent semiconductor devices, and adjacent subfin regions 108. Dielectric layer 106 can be any suitable dielectric material, such as silicon dioxide, aluminum oxide, or silicon oxycarbonitride.

Semiconductor devices 101 each include a subfin region 108, in this example. According to some embodiments, subfin region 108 comprises the same semiconductor material as substrate 102 and is adjacent to dielectric layer 106. According to some embodiments, nanoribbons 104 (or other semiconductor bodies) extend between a source and a drain region in the first direction to provide an active region for a transistor (e.g., the semiconductor region beneath the gate). The source and drain regions are not shown in the cross-section of FIG. 1A, but are seen in the top-down view of FIG. 1B where nanoribbons 104 of each semiconductor device 101 extend between first source or drain regions 110. FIG. 1B also illustrates a dielectric fill 114 between source or drain regions 110 of a given source/drain trench extending along a second direction (e.g., across the page in FIG. 1A). Dielectric fill 114 may include any suitable dielectric material, such as silicon dioxide. According to some embodiments, spacer structures 112 extend around the ends of nanoribbons 104 and along sidewalls of the gate structures between spacer structures 112. Spacer structures 112 may include a dielectric material, such as silicon nitride, and may be deposited in a conformal fashion or other suitable deposition process and be etched to a desired thickness (e.g., 2 nm to 10 nm).

According to some embodiments, the source and drain regions 110 are epitaxial regions that are provided using an etch-and-replace process. Any semiconductor materials suitable for source and drain regions can be used (e.g., group IV and group III-V semiconductor materials). The source and drain regions 110 may include multiple layers such as liners and capping layers to improve contact resistance. In any such cases, the composition and doping of the source and drain regions 110 may be the same or different, depending on the polarity of the transistors. In an example, silicon doped with phosphorous may be used for n-type source or drain regions while silicon germanium doped with boron may be used for p-type source or drain regions. Any number of source and drain configurations and materials can be used.

According to some embodiments, each semiconductor device 101 includes a gate structure extending over nanoribbons 104 along the second direction across the page of FIG. 1A. The second direction may be orthogonal to the first direction. Each gate structure includes a respective gate dielectric 116 and a gate electrode 118. Gate dielectric 116 represents any number of dielectric layers present between nanoribbons 104 and gate electrode 118. Gate dielectric 116 may also be present on the surfaces of other structures within the gate trench, such as on subfin region 108. Gate dielectric 116 may include any suitable gate dielectric material(s). In some embodiments, gate dielectric 116 includes a layer of native oxide material (e.g., silicon dioxide) on the nanoribbons or other semiconductor regions making up the channel region of the devices, and a layer of high-K dielectric material (e.g., hafnium oxide) on the native oxide.

Gate electrode 118 may represent any number of conductive layers, such as any metal, metal alloy, or doped polysilicon layers. In some embodiments, gate electrode 118 includes one or more workfunction metals around nanoribbons 104. In some embodiments, one of semiconductor devices 101 is a p-channel device that includes a workfunction metal having titanium around its nanoribbons 104. In some embodiments, one of semiconductor devices 101 is an n-channel device that includes a workfunction metal having tungsten around its nanoribbons 104. Gate electrode 118 may also include a fill metal or other conductive material (e.g., tungsten, ruthenium, molybdenum, cobalt) around the workfunction metals to provide the whole gate electrode structure. In some embodiments, a gate cap 119 may be formed over gate electrode 118 to protect the underlying material during processing. Gate cap 119 may be any suitable dielectric material, such as silicon nitride.

According to some embodiments, adjacent gate structures may be separated along the second direction (e.g., across the page) by a gate cut 120, which acts like a dielectric barrier or wall between gate structures. Gate cut 120 extends vertically (e.g., in a third direction) through a portion of the entire thickness of the adjacent gate structures on either side of gate cut 120. In some embodiments, gate cut 120 rests on a top surface of dielectric layer 106 (e.g., does not extend into dielectric layer 106). According to some embodiments, gate cut 120 is formed from various dielectric materials. In an example, gate cut 120 includes a dielectric liner along an outer edge of gate cut 120 and a dielectric fill on the dielectric liner. According to some embodiments, the dielectric liner includes a high-k dielectric material, such as silicon nitride, and the dielectric fill includes a medium-k or low-k dielectric material (e.g., a dielectric having a dielectric constant of about 4.5 or less), such as silicon dioxide, porous silicon dioxide, or flowable oxide. In other examples, gate cut 120 includes a single dielectric material, such as silicon nitride, silicon oxynitride, or silicon oxycarbonitride. In some embodiments, gate cut 120 includes one or more airgaps or voids, which may further lower the dielectric constant of gate cut 120.

According to some embodiments, gate cut 120 is self-aligned within the gate trench between adjacent devices such that a distance (d) between each edge of the gate cut 120 and the corresponding nanoribbons 104 along a common plane is substantially the same (e.g., distance d on one side is within 1 nm of distance d on the other side). The distance (d) may vary depending on the device density, but may generally be between about 5 nm and about 20 nm. According to some embodiments, gate cut 120 extends in the first direction across the entire width of the gate trench as seen in FIG. 1B but is confined to the gate trench. Accordingly, gate cut 120 does not extend beyond spacer structures 112 along the first direction. As will be discussed in more detail herein, gate cut 120 is formed after the formation of gate dielectric 116, but before the formation of gate electrode 118, such that gate dielectric 116 does not extend along the sidewalls of gate cut 120, although ends of the gate dielectric 116 may abut the sidewalls of gate cut 120. Accordingly, the sidewalls of gate cut 120 that extend along the first direction may directly contact gate electrode 118 and the sidewalls of gate cut 120 that extend along the second direction may directly contact spacer structures 112.

Due to the fabrication process used to form gate cut 120, as described in more detail herein, gate cut 120 includes a first section having a first width w₁ along the second direction, and a second section having a second width w₂ along the second direction. The first width w₁ of the first section is greater than the second width w₂ of the second section, although exact dimensions may vary. In some embodiments, first width w₁ is at 50%, at least 75%, or at least 100% greater than second width w₂. As can be seen in FIG. 1B, gate cut 120 may also include narrower end sections along the first direction with the wider section provided between the narrower end sections. The narrower end sections of gate cut 120 directly contact spacer structures 112, according to some embodiments.

As noted above, gate cut 120 may not extend through an entire thickness of the adjacent gate structures. To complete the isolation of the gates, a dielectric plug 122 may extend between a top of the gate trench and a top surface of gate cut 120. Dielectric plug 122 may include any suitable dielectric material. In some examples, dielectric plug 122 includes the same dielectric material as gate cut 120. The combination of gate cut 120 and dielectric plug 122 extends through the entire height of the adjacent gate structures within the gate trench to isolate the adjacent gate structures. Accordingly, dielectric plug 122 extends across the entire width of the gate trench in the first direction between spacer structures 112.

### Fabrication Methodology

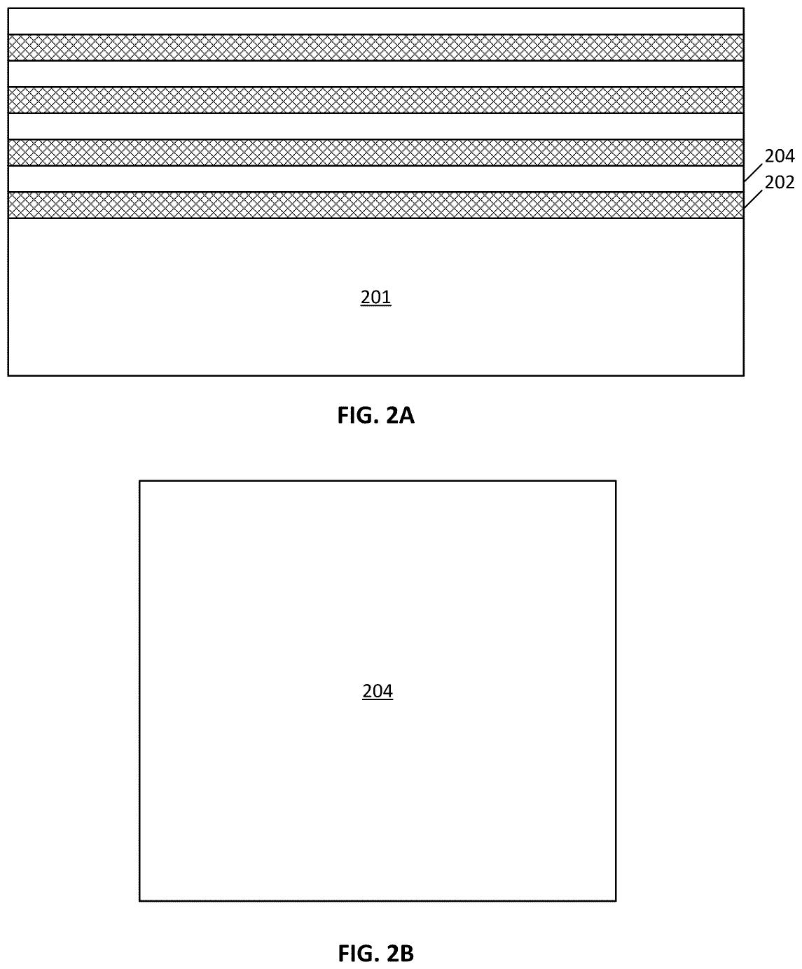

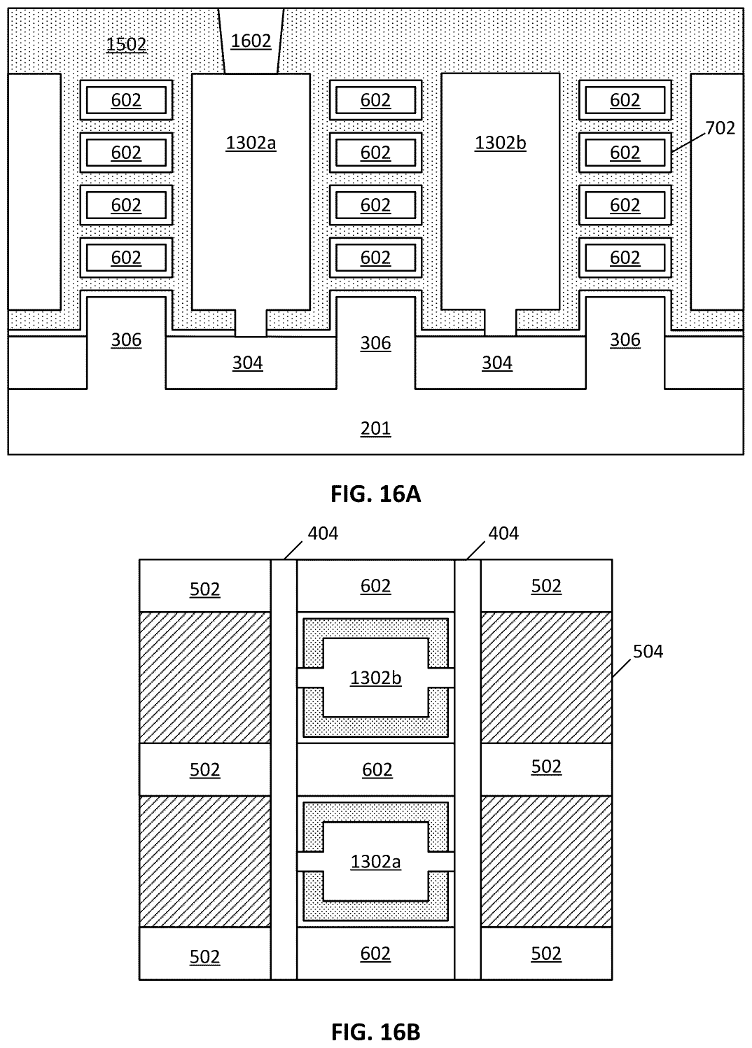

FIGS. 2A-16A and 2B-16B include cross-sectional and plan views, respectively, that collectively illustrate an example process for forming an integrated circuit with semiconductor devices that have self-aligned gate cuts confined within the gate trench between the devices, in accordance with an embodiment of the present disclosure. FIGS. 2A-16A represent a similar cross-sectional view as that of FIG. 1A across a series of semiconductor devices, while FIGS. 2B-16B represent the corresponding plan view at each stage of the fabrication. Each set of figures sharing the same letter shows an example structure that results from the process flow up to that point in time, so the depicted structure evolves as the process flow continues, culminating in the structure shown in FIGS. 16A-16B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure. Although the fabrication of two gate cuts are illustrated in the aforementioned figures, it should be understood that any number of similar gate cuts can be fabricated across the integrated circuit using the same processes discussed herein.

FIGS. 2A and 2B illustrate a cross-sectional view taken through a substrate 201 and a plan view across substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201. The plan view of FIG. 2B illustrates the topmost semiconductor layer 204 of the layer stack.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

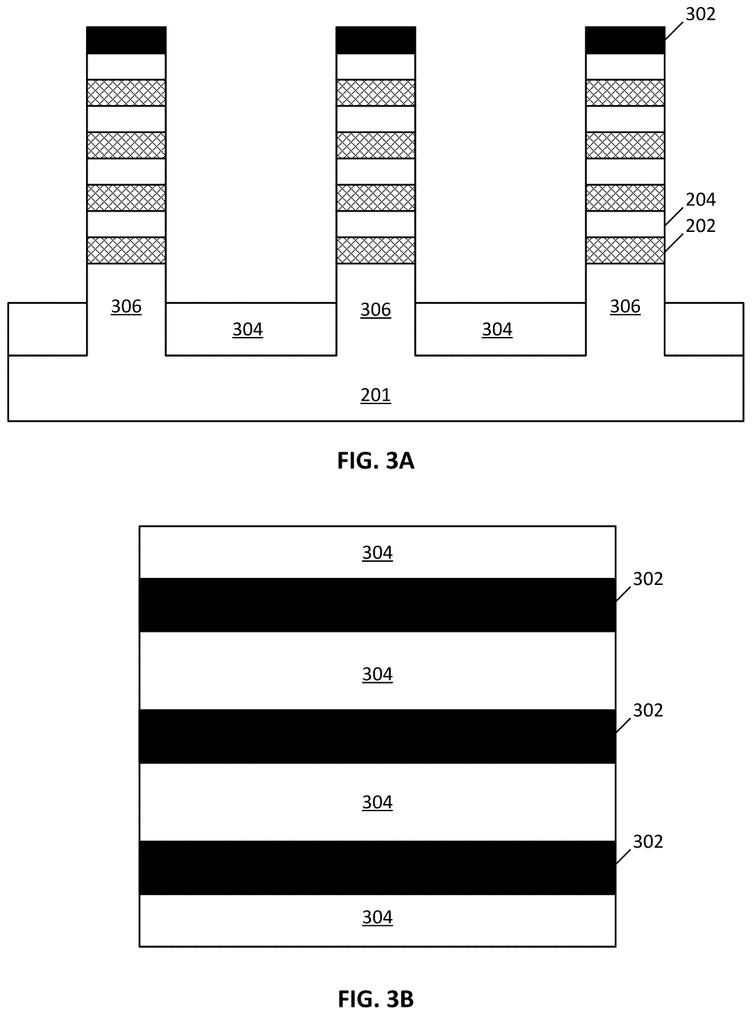

FIGS. 3A and 3B depict the cross-section and plan views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. The rows of fins extend lengthwise in a first direction (e.g., into and out of the page of FIG. 3A).

According to some embodiments, an anisotropic etching process through the layer stack continues into at least a portion of substrate 201. The etched portion of substrate 201 may be filled with a dielectric layer 304 that acts as shallow trench isolation (STI) between adjacent fins. Dielectric layer 304 may be any suitable dielectric material such as silicon dioxide. Subfin regions 306 represent remaining portions of substrate 201 between dielectric layer 304, according to some embodiments. Dielectric layer 304 may be formed by blanket deposition of dielectric material across the structure followed by isotropically etching back the dielectric material to a final thickness adjacent to subfin regions 306. According to some embodiments, a top surface of dielectric layer 304 is recessed below a top surface of subfin regions 306, as illustrated in FIG. 3A.

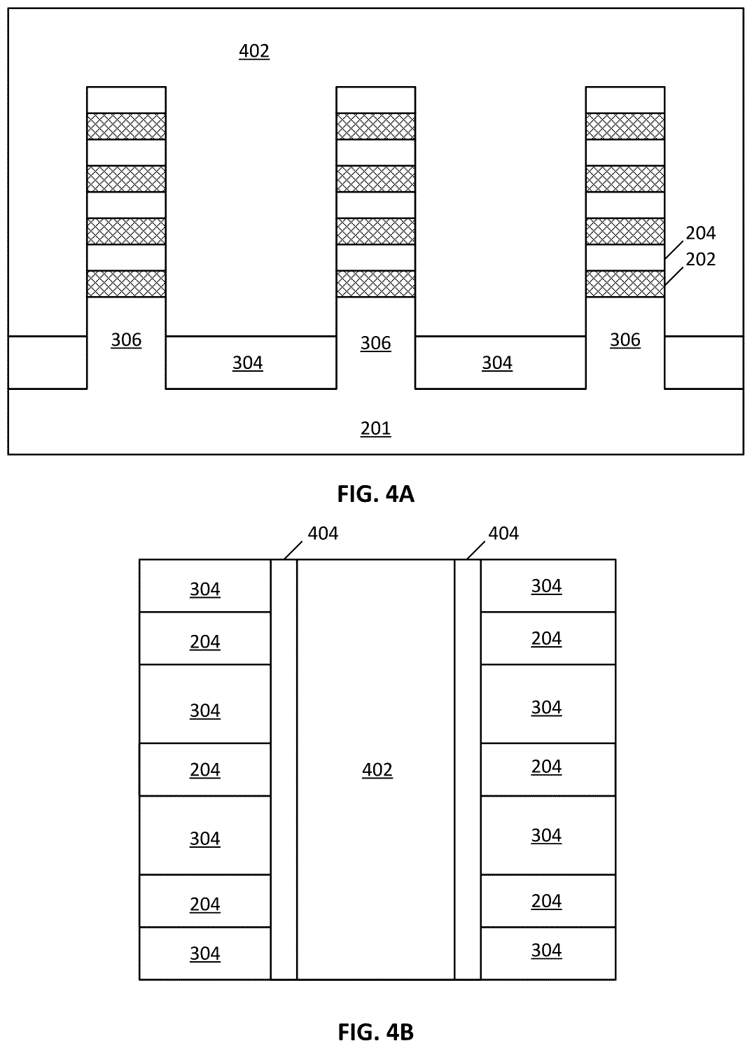

FIGS. 4A and 4B depict the cross-section and plan views of the structure shown in FIGS. 3A and 3B, respectively, following the formation of a sacrificial gate 402 extending across the fins in a second direction different from the first direction, according to some embodiments. Sacrificial gate 402 may extend across the fins in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fins. In some examples, sacrificial gate 402 includes polysilicon.

Following the formation of sacrificial gate 402, spacer structures 404 may be formed on the sidewalls of sacrificial gate 402. According to some embodiments, a dielectric material is blanket deposited across the structure and etched back to form the spacer structures 404 on the sidewalls of any structures extending above substrate 201. Spacer structures 404 extend along the sides of sacrificial gate 402 along the second direction as illustrated in FIG. 4B. In some embodiments, spacer structures may also form on the sides of the fins not under sacrificial gate 402. Spacer structures 404 may be any suitable dielectric material, such as silicon nitride.

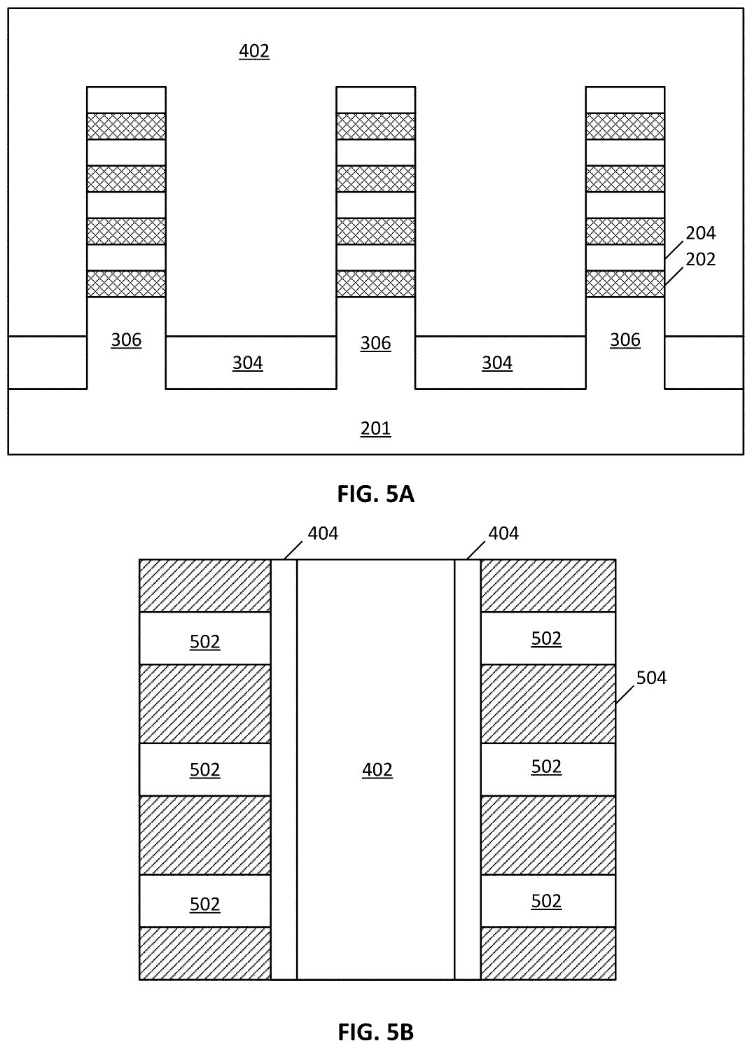

FIGS. 5A and 5B depict the cross-section and plan views of the structure shown in FIGS. 4A and 4B, respectively, following the removal of any exposed fins and the subsequent formation of source or drain regions 502 at the ends of the fins, according to some embodiments. The exposed fin portions (e.g., not protected by either sacrificial gate 402 or spacer structures 404) may be removed using any anisotropic etching process, such as reactive ion etching (RIE). The removal of the exposed fin portions creates source or drain trenches that alternate with gate trenches (currently filled with sacrificial gates 402) along the first direction, according to some embodiments.

According to some embodiments, source or drain regions 502 may be formed from the exposed ends of the fins within the source/drain trench. The source or drain regions may be formed in the areas that had been previously occupied by the exposed fins adjacent to spacer structures 404. According to some embodiments, source or drain regions 502 are epitaxially grown from the exposed semiconductor material at the ends of semiconductor layers 204. In some example embodiments, any of source or drain regions 502 can be NMOS source or drain regions (e.g., epitaxial silicon), or PMOS source or drain regions (e.g., epitaxial SiGe).

According to some embodiments, a dielectric fill 504 is provided within the source/drain trench. In some examples, dielectric fill 504 occupies a remaining volume within the source/drain trench around and possibly over source or drain regions 502. Dielectric fill 504 may be any suitable dielectric material, such as silicon dioxide. In some examples, dielectric fill 504 extends up to and planar with a top surface of spacer structures 404 (e.g., following a polishing procedure).

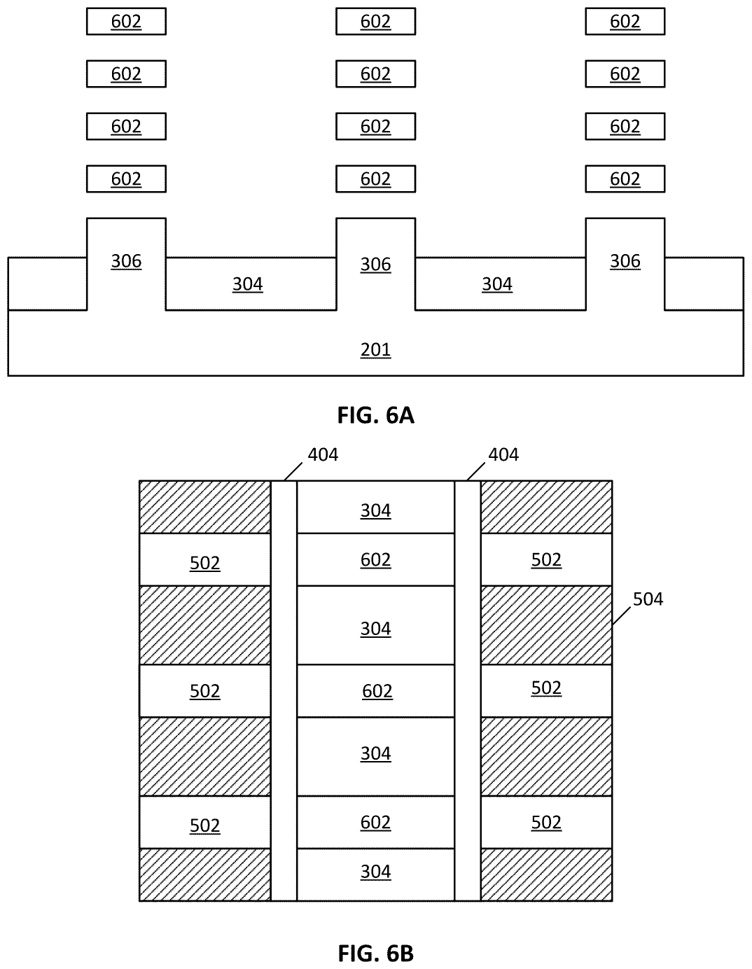

FIGS. 6A and 6B depict the cross-section and plan views of the structure shown in FIGS. 5A and 5B, respectively, following the removal of sacrificial gate 402 and the removal of sacrificial layers 202, according to some embodiments. In examples where any gate masking layers are still present, they may also be removed at this time. Once sacrificial gate 402 is removed, the fins that had been beneath sacrificial gate 402 are exposed.

In the example where the fins include alternating semiconductor layers, sacrificial layers 202 are selectively removed to release nanoribbons 602 that extend between corresponding source or drain regions 502. Each vertical set of nanoribbons 602 represents the semiconductor or channel region of a different semiconductor device. It should be understood that nanoribbons 602 may also be nanowires or nanosheets (e.g., from a forksheet arrangement) or fins (e.g., for a finFET arrangement). Sacrificial gate 402 and sacrificial layers 202 may be removed using the same isotropic etching process or different isotropic etching processes. Also, note that source or drain regions 502 abut or otherwise contact respective ends of nanoribbons 602, underneath spacer structures 404, so as to provide a transistor conduction path from the source region to the drain region, when the gate is properly biased (such as shown in FIG. 1B, where source and drain regions 110 abut semiconductor regions 104).

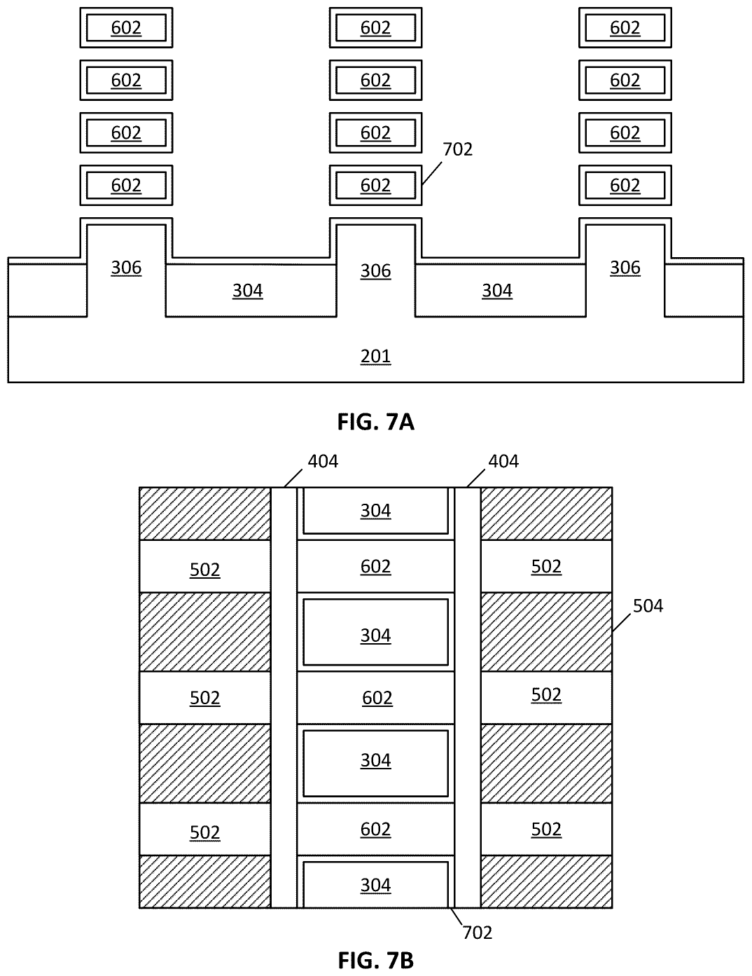

FIGS. 7A and 7B depict the cross-section and plan views of the structure shown in FIGS. 6A and 6B, respectively, following the formation of a gate dielectric 702 over any exposed surfaces within the gate trench, according to some embodiments. Gate dielectric 702 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 702 includes a layer of hafnium oxide with a thickness between about 1 nm and about 5 nm. In some embodiments, gate dielectric 702 may include one or more silicates (e.g., titanium silicate, tungsten silicate, niobium silicate, and silicates of other transition metals). In some cases, gate dielectric 702 may include a first layer on nanoribbons 602, and a second layer on the first layer. The first layer can be, for instance, an oxide of the semiconductor material of nanoribbons 602 (e.g., silicon dioxide) and the second layer can be a high-k dielectric material (e.g., hafnium oxide). More generally, gate dielectric 702 can include any number of dielectric layers. According to some embodiments, gate dielectric 702 forms along all surfaces exposed within the gate trench, such as along inner sidewalls of the spacer structures (as seen in FIG. 7B) and along the top surfaces of dielectric layer 304 and subfin regions 306. In some embodiments, gate dielectric 702 may be annealed along with another deposited material layer (e.g., layer of titanium nitride) to affect the threshold voltage of the transistors.

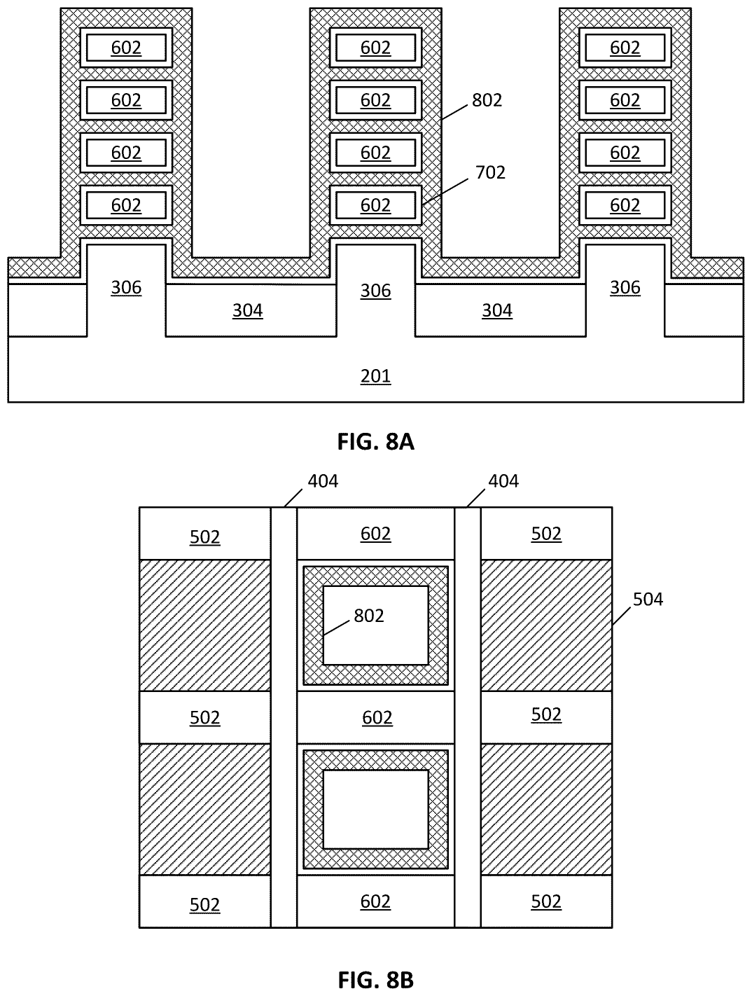

FIGS. 8A and 8B depict the cross-section and plan views of the structure shown in FIGS. 7A and 7B, respectively, following the formation of a sacrificial structure 802 within the gate trench and over the semiconductor material of the transistors, according to some embodiments. Sacrificial structure 802 may include any suitable material that can be safely removed at a later time without damaging surrounding materials, such as gate dielectric 702 or nanoribbons 602. In some examples, sacrificial structure 802 includes a layer of aluminum oxide. In some examples, sacrificial structure 802 includes a dielectric liner, such as a thin liner of silicon dioxide over the layer of aluminum oxide. In general, sacrificial structure 802 is conformally deposited over the transistor structures such that there is space left between the transistor structures within the gate trench. Accordingly, sacrificial structure 802 may be deposited using CVD or ALD. The thickness of sacrificial structure 802 has a direct impact on the resulting width of the gate cuts to be formed between the devices, as will be described in more detail herein. In some examples, the thickness of sacrificial structure 802 is between about 5 nm and about 15 nm.

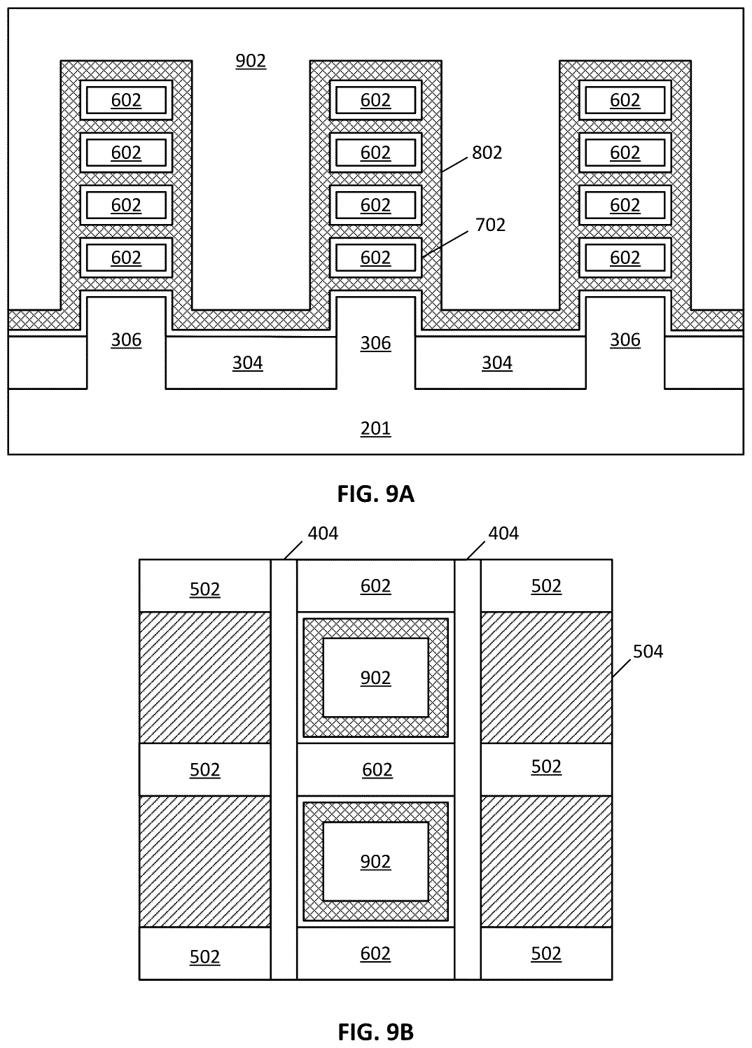

FIGS. 9A and 9B depict the cross-section and plan views of the structure shown in FIGS. 8A and 8B, respectively, following the formation of a mask material 902 within the gate trench, according to some embodiments. Mask material 902 may be deposited within the gate trench and subsequently polished until a top surface of mask material 902 is substantially coplanar with a top surface of spacer structures 404. Mask material 902 may be any suitable hard mask material with a high degree of etch selectivity compared to the surrounding materials. In some examples, mask material 902 includes carbon hard mask (CHM).

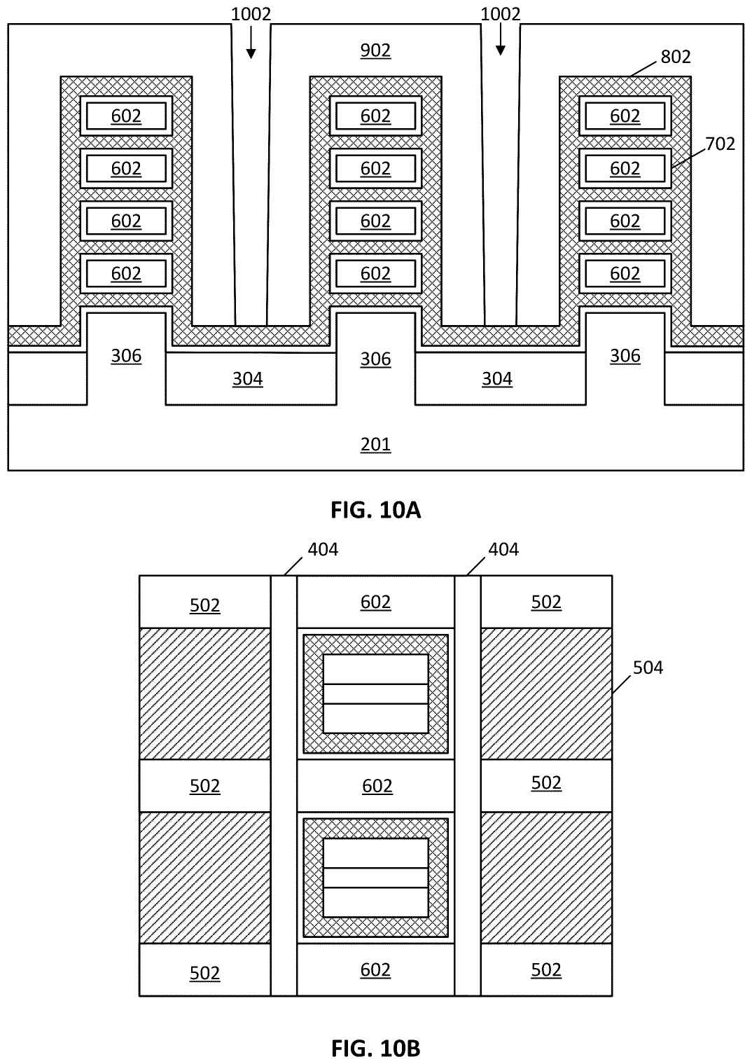

FIGS. 10A and 10B depict the cross-section and plan views of the structure shown in FIGS. 9A and 9B, respectively, following the formation of recesses 1002 through mask material 902, according to some embodiments. Recesses 1002 may be trench-shaped recesses that extend along the first direction across the gate trench between sacrificial structure 802 on the sidewalls of spacer structures 404, as seen in FIG. 10B. Recesses 1002 may extend to a depth through an entire height of mask material 902 to expose a portion of sacrificial structure 802 at the bottom of the gate trench between adjacent semiconductor devices. An RIE process may be used to etch through mask material 902 while stopping on sacrificial structure 802. According to some embodiments, the alignment of recesses 1002 is not critical, such that recesses 1002 do not need to be centrally aligned along the second direction between the adjacent semiconductor devices. For example, recesses 1002 may be formed through mask structure 902 anywhere between adjacent semiconductor devices along the second direction.

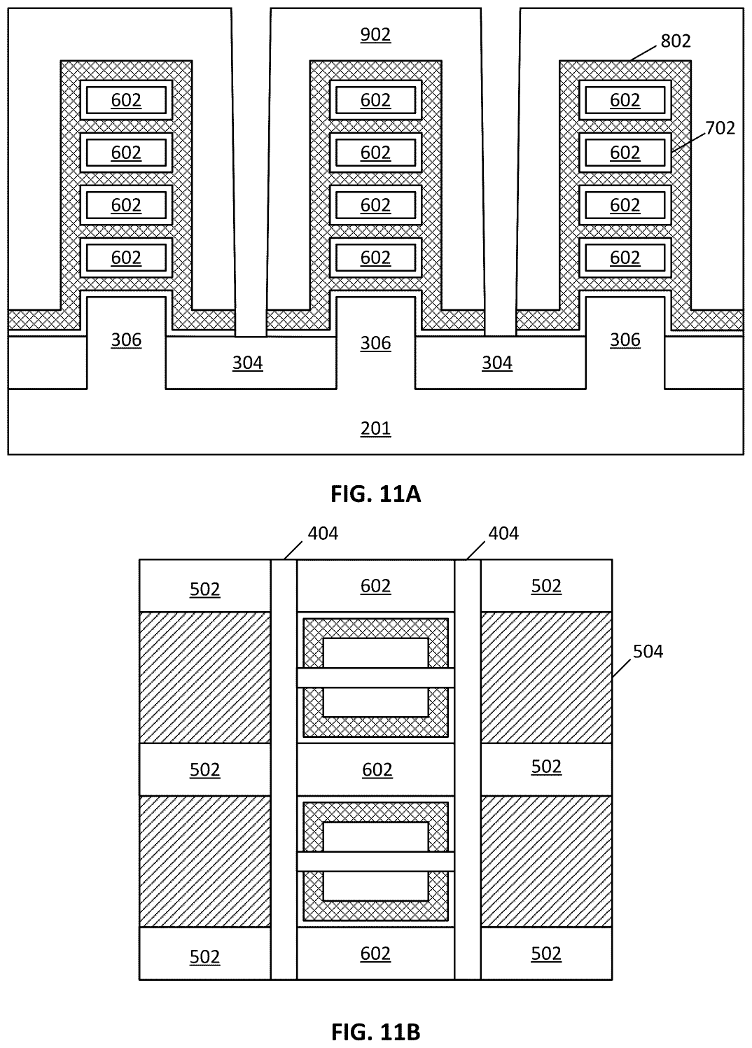

FIGS. 11A and 11B depict the cross-section and plan views of the structure shown in FIGS. 10A and 10B, respectively, following an additional etching operation to remove the exposed sacrificial structure 802 within recesses 1002, according to some embodiments. A directional RIE process may be used to remove sacrificial structure 802 from the bottom of recesses 1002 (as shown in FIG. 11A) and at both ends of recesses 1002 (as shown in FIG. 11B). According to some embodiments, the same etch may also be used to remove exposed portions of gate dielectric 702 within recesses 1002 following the removal of sacrificial structure 802 within recesses 1002. In some examples, a different RIE process is used to remove gate dielectric 702. In some examples, an isotropic etch (e.g., a wet etch process) is used to remove the sidewall portions of sacrificial structure 802 and/or the sidewalls portions of gate dielectric 702 within recesses 1002.

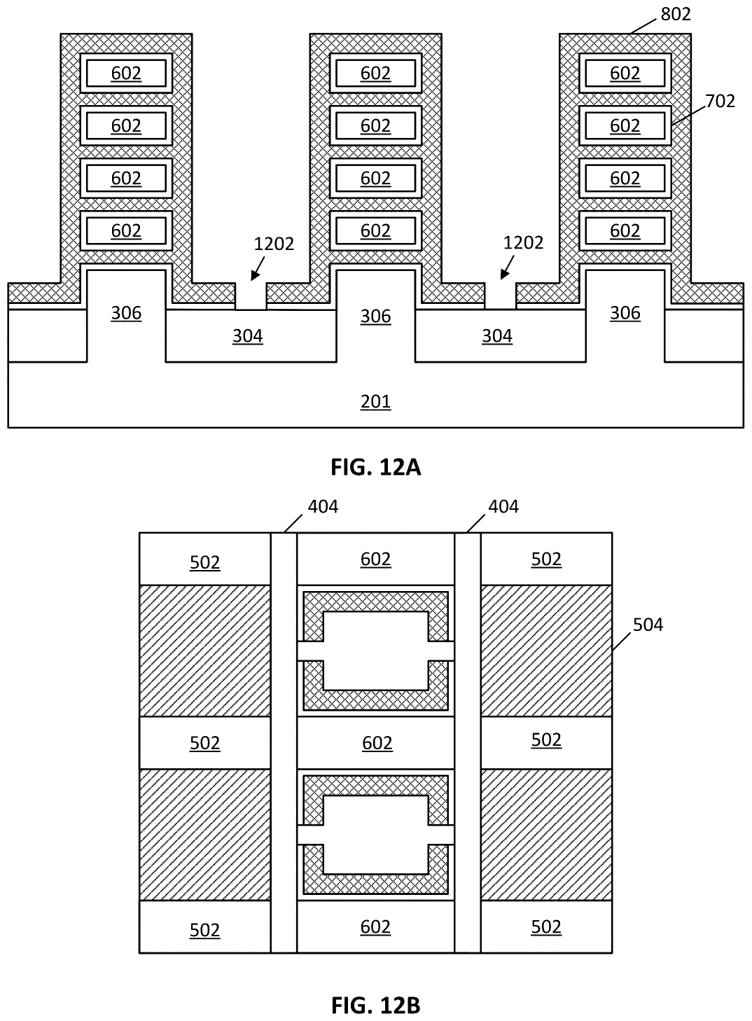

FIGS. 12A and 12B depict the cross-section and plan views of the structure shown in FIGS. 11A and 11B, respectively, following the removal of mask material 902, according to some embodiments. Mask material 902 may be removed using any suitable isotropic etching process. In some examples, mask material 902 is removed using an ashing process. The removal of mask material 902 reveals cavities 1202 through an entire thickness of sacrificial structure 802. As discussed above, cavities 1202 may run along the bottom of the gate trench (e.g., exposing a top surface of dielectric fill 304) and also along the sides of the gate trench (e.g., exposing sidewall surfaces of spacer structures 404).

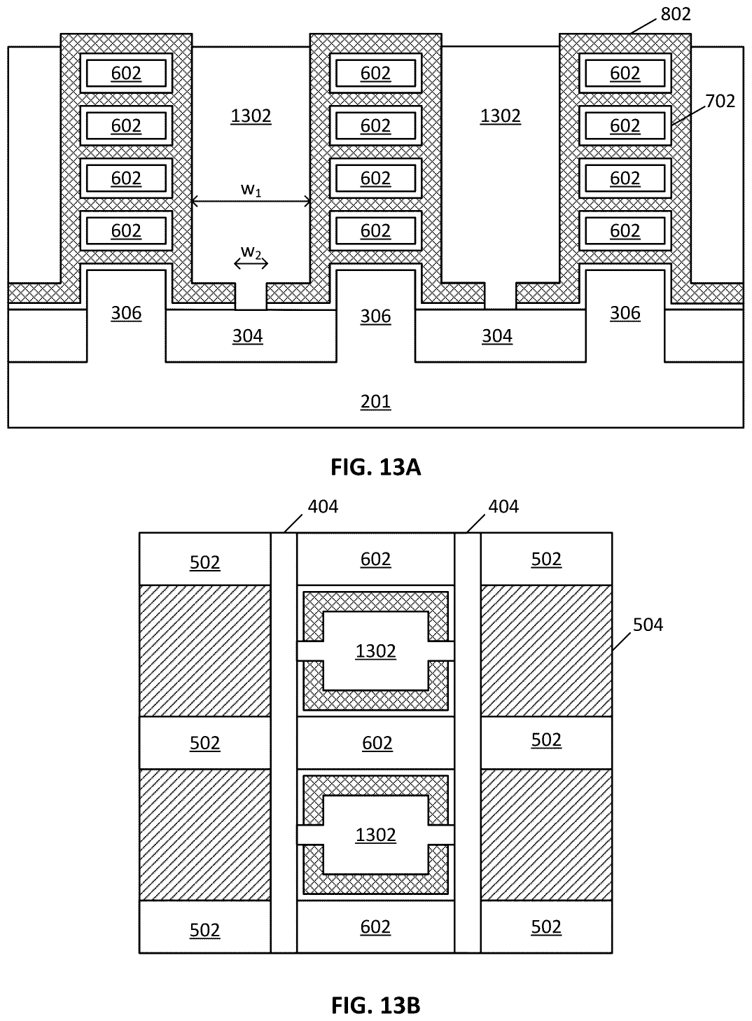

FIGS. 13A and 13B depict the cross-section and plan views of the structure shown in FIGS. 12A and 12B, respectively, following the formation of gate cuts 1302 within the gate trench between semiconductor devices, according to some embodiments. Gate cuts 1302 may include any suitable dielectric material, such as silicon nitride, silicon oxynitride, or silicon oxycarbonitride. The dielectric material of gate cuts 1302 may be deposited using any suitable deposition technique, such as CVD, PECVD, flowable dielectric, or spin-on dielectric. According to some embodiments, the dielectric material of gate cuts 1302 is deposited within the gate trench and subsequently recessed using any suitable isotropic etching process until the top surface of sacrificial structure 802 is exposed. Accordingly, a top surface of gate cuts 1302 may be recessed below the top surface of sacrificial structure 802 within the gate trench. Since the dielectric material of gate cuts 1302 fills the space between sacrificial structure 802, gate cuts 1302 are self-aligned directly between adjacent semiconductor devices along the gate trench.

According to some embodiments, the dielectric material of gate cuts 1302 also fills cavities 1202, such that gate cuts 1302 extend across the entire width of the gate trench from one spacer structure 404 to the opposite spacer structure 404. A bottom surface of gate cuts 1302 may also contact dielectric fill 304. The wider section of gate cuts 1302 between nanoribbons 602 has a first width w₁, and the narrower section of gate cuts 1302 within the cavities along the bottom and sides of the structure has a second width w₂. According to some embodiments, the first width w₁ is at least 25%, at least 50%, at least 75%, or at least 100% greater than the second width w₂.

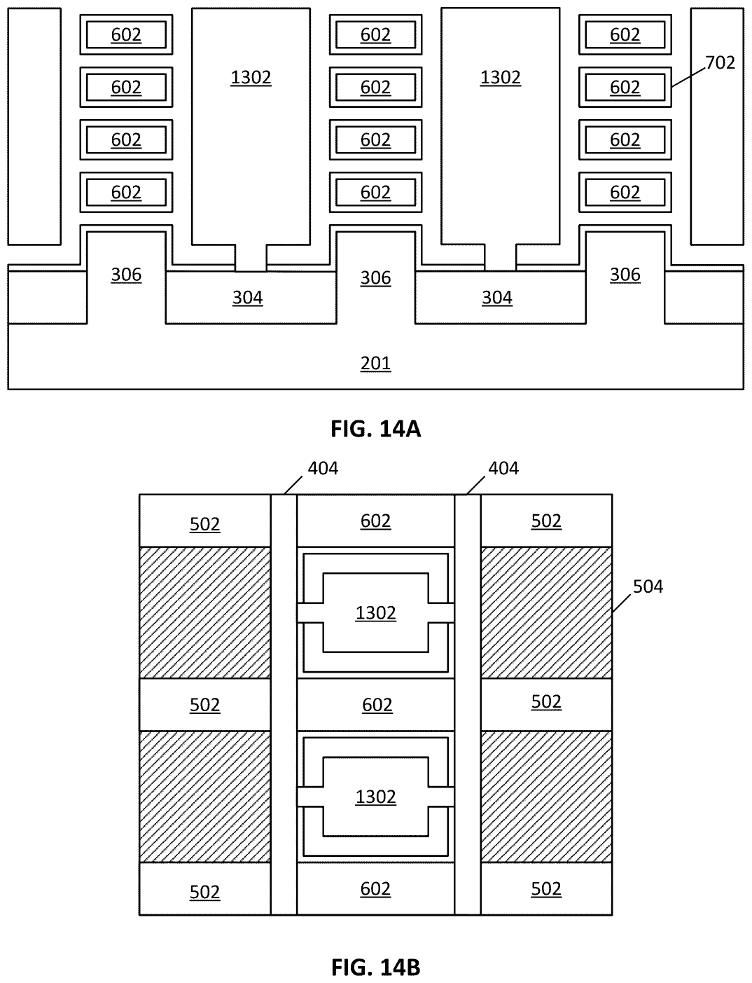

FIGS. 14A and 14B depict the cross-section and plan views of the structure shown in FIGS. 13A and 13B, respectively, following the removal of sacrificial structure 802, according to some embodiments. Sacrificial structure 802 may be removed using any suitable isotropic etching process. According to some embodiments, gate dielectric 702 remains around nanoribbons 602 and over subfin portions 306. However, gate dielectric 702 does not extend over the sidewalls of gate cuts 1302.

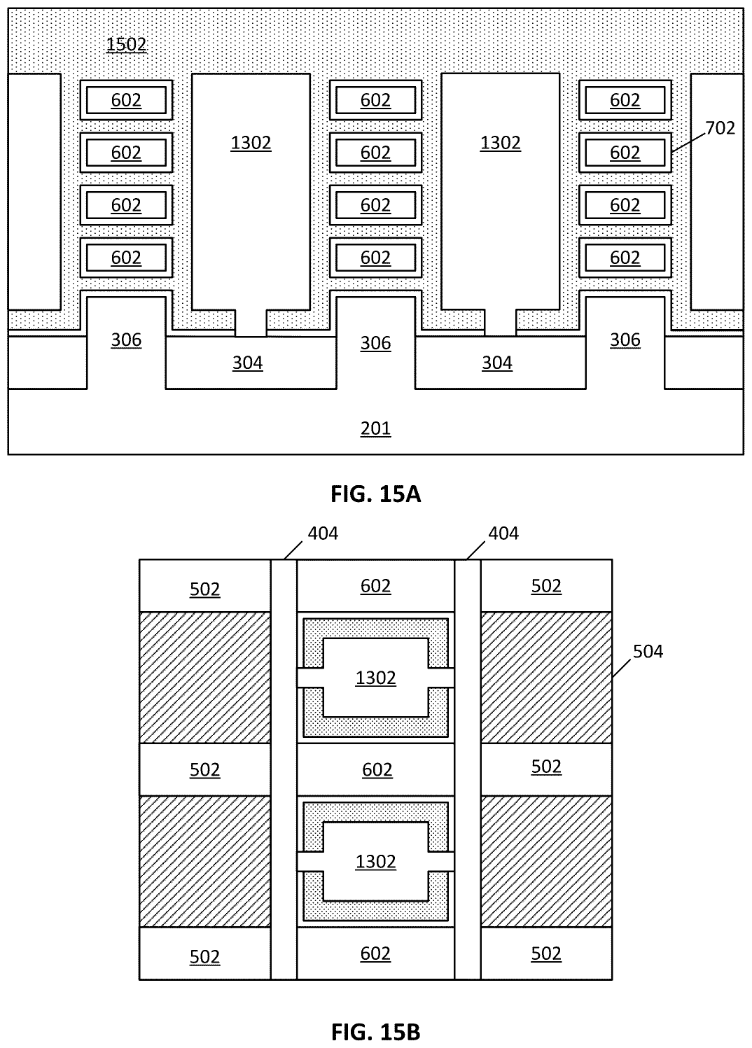

FIGS. 15A and 15B depict the cross-section and plan views of the structure shown in FIGS. 13A and 13B, respectively, following the formation of a gate electrode 1502 around nanoribbons 602 and over gate cuts 1302 within the gate trench, according to some embodiments. Gate electrode 1502 may include any number of conductive layers. The conductive gate electrode 1502 may be deposited using electroplating, electroless plating, CVD, PECVD, ALD, or PVD, to name a few examples. In some embodiments, gate electrode 1502 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 1502 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure, the entire structure may be polished or planarized such that the top surface of the gate structure (e.g., top surface of gate electrode 1502) is substantially coplanar with the top surface of other semiconductor elements, such as spacer structures 404 that define the gate trench.

FIGS. 16A and 16B depict the cross-section and plan views of the structure shown in FIGS. 15A and 15B, respectively, following the formation of a dielectric plug 1602 on a corresponding gate cut 1302a, according to some embodiments. A recess may be etched through a portion of gate electrode 1502 to expose a top surface of gate cut 1302a. The recess may be filled with one or more dielectric materials to form dielectric plug 1602. A top surface of dielectric plug 1602 may be polished such that it is substantially coplanar with a top surface of gate electrode 1502. In some other examples, the top surface of dielectric plug 1602 is substantially coplanar with a top surface of a dielectric cap layer over gate electrode 1502. Dielectric plug 1602 extends across the entire with of the gate trench (e.g., between spacer structures 404 along the first direction), such that the combined structure of gate cut 1302a and dielectric plug 1602 isolates the gate structures on either side of gate cut 1302a. Dielectric plug 1602 may include a single dielectric material, such as silicon nitride, or a dielectric liner and a dielectric fill on the dielectric liner. The dielectric liner may include any suitable high-k dielectric material (e.g., silicon nitride), while the dielectric fill may include any suitable low-k dielectric material (e.g., silicon dioxide).

According to some embodiments, another gate cut 1302b does not have a dielectric plug formed over it, such that gate electrode 1502 extends over the top of gate cut 1302b within the gate trench. Accordingly, the gates of the adjacent semiconductor devices on either side of gate cut 1302b are connected together. This may be a common circuit configuration to connect the gate of an NMOS device to the gate of a PMOS device. Furthermore, gate cut 1302a may be located along a cell boundary.

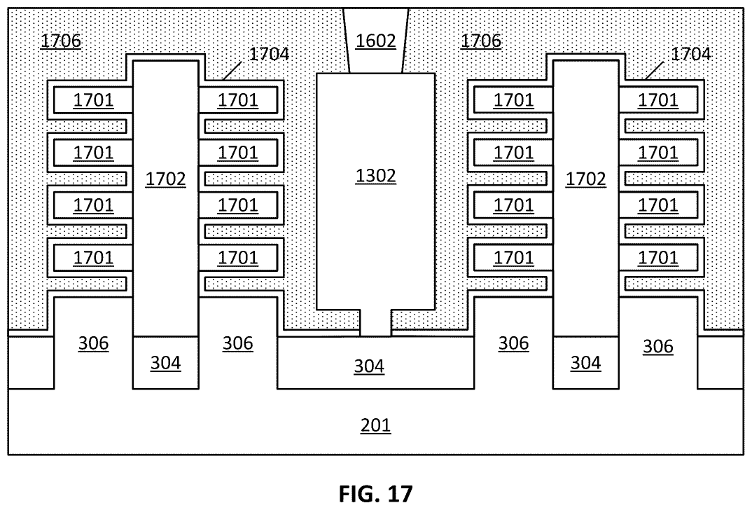

As discussed above, the techniques described herein may be used with any type of transistor architecture, such as finFET or forksheet, to provide isolation between adjacent devices. FIG. 17 illustrates an example portion of an integrated circuit with forksheet devices separated by gate cut 1302 with a corresponding dielectric plug 1602, according to some embodiments. In the forksheet example, nanosheets 1701 extend from a dielectric spine 1702 to form closely adjacent devices. Typically, nanosheets 1701 on one side of dielectric spine 1702 are part of an NMOS device and nanosheets 1701 on the opposite side of dielectric spine 1702 are part of a PMOS device. A gate dielectric 1704 and gate electrode 1706 provide the gate structure around nanosheets 1701. Gate cut 1302 may be positioned at a cell boundary between adjacent forksheet devices. According to some embodiments, dielectric spine 1702 comprises one or more dielectric materials, such as a dielectric liner and a dielectric fill on the dielectric liner. Dielectric spine 1702 may be formed before forming gate dielectric 1704, such that gate dielectric 1702 is formed over all exposed surfaces of dielectric spine 1702.

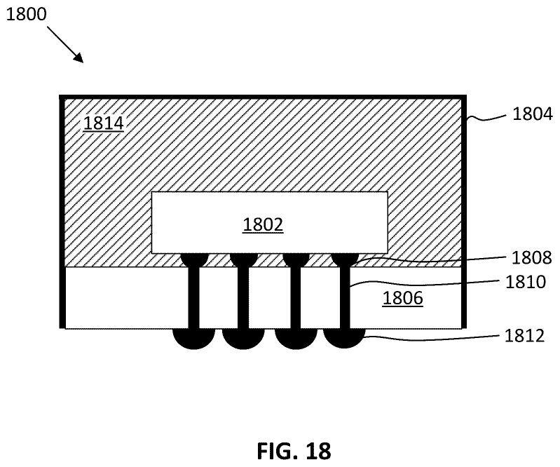

FIG. 18 illustrates an example embodiment of a chip package 1800, in accordance with an embodiment of the present disclosure. As can be seen, chip package 1800 includes one or more dies 1802. One or more dies 1802 may include at least one integrated circuit having semiconductor devices, such as any of the semiconductor devices disclosed herein. One or more dies 1802 may include any other circuitry used to interface with other devices formed on the dies, or other devices connected to chip package 1800, in some example configurations.

As can be further seen, chip package 1800 includes a housing 1804 that is bonded to a package substrate 1806. The housing 1804 may be any standard or proprietary housing, and may provide, for example, electromagnetic shielding and environmental protection for the components of chip package 1800. The one or more dies 1802 may be conductively coupled to a package substrate 1806 using connections 1808, which may be implemented with any number of standard or proprietary connection mechanisms, such as solder bumps, ball grid array (BGA), pins, or wire bonds, to name a few examples. Package substrate 1806 may be any standard or proprietary package substrate, but in some cases includes a dielectric material having conductive pathways (e.g., including conductive vias and lines) extending through the dielectric material between the faces of package substrate 1806, or between different locations on each face. In some embodiments, package substrate 1806 may have a thickness less than 1 millimeter (e.g., between 0.1 millimeters and 0.5 millimeters), although any number of package geometries can be used. Additional conductive contacts 1812 may be disposed at an opposite face of package substrate 1806 for conductively contacting, for instance, a printed circuit board (PCB). One or more vias 1810 extend through a thickness of package substrate 1806 to provide conductive pathways between one or more of connections 1808 to one or more of contacts 1812. Vias 1810 are illustrated as single straight columns through package substrate 1806 for ease of illustration, although other configurations can be used (e.g., damascene, dual damascene, through-silicon via, or an interconnect structure that meanders through the thickness of substrate 1806 to contact one or more intermediate locations therein). In still other embodiments, vias 1810 are fabricated by multiple smaller stacked vias, or are staggered at different locations across package substrate 1806. In the illustrated embodiment, contacts 1812 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1812, to inhibit shorting.

In some embodiments, a mold material 1814 may be disposed around the one or more dies 1802 included within housing 1804 (e.g., between dies 1802 and package substrate 1806 as an underfill material, as well as between dies 1802 and housing 1804 as an overfill material). Although the dimensions and qualities of the mold material 1814 can vary from one embodiment to the next, in some embodiments, a thickness of mold material 1814 is less than 1 millimeter. Example materials that may be used for mold material 1814 include epoxy mold materials, as suitable. In some cases, the mold material 1814 is thermally conductive, in addition to being electrically insulating.

### Methodology

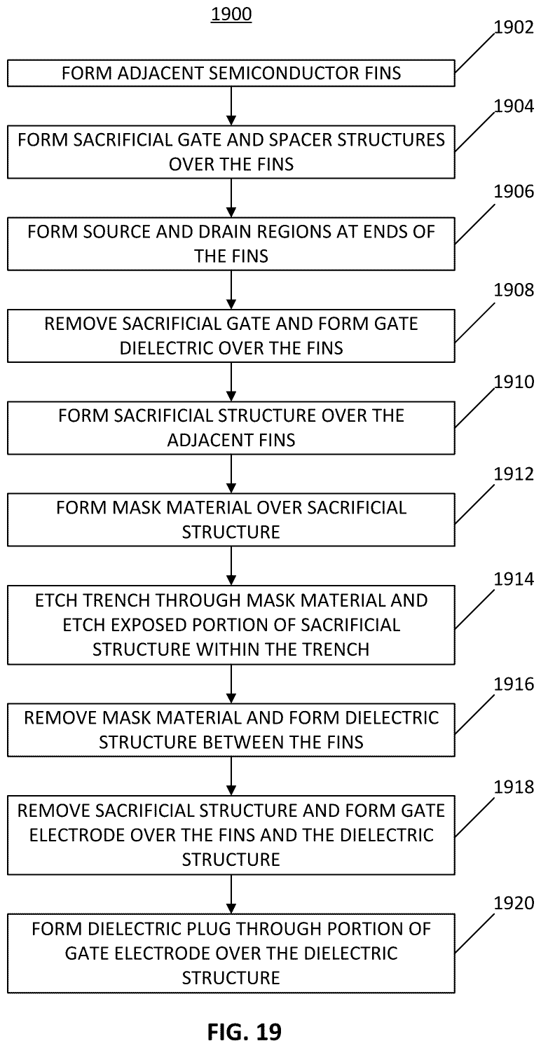

FIG. 19 is a flow chart of a method 1900 for forming at least a portion of an integrated circuit, according to an embodiment. Various operations of method 1900 may be illustrated in FIGS. 2A-16A and 2B-16B. However, the correlation of the various operations of method 1900 to the specific components illustrated in the aforementioned figures is not intended to imply any structural and/or use limitations. Rather, the aforementioned figures provide one example embodiment of method 1900. Other operations may be performed before, during, or after any of the operations of method 1900. For example, method 1900 does not explicitly describe all processes that are performed to form common transistor structures. Some of the operations of method 1900 may be performed in a different order than the illustrated order.

Method 1900 begins with operation 1902 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 1900 continues with operation 1904 where a sacrificial gate and spacer structures are formed over adjacent fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 1900 continues with operation 1906 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 1900 continues with operation 1908 where the sacrificial gate is removed and a gate dielectric is formed. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate dielectric may be formed over the exposed semiconductor regions between the spacer structures. The gate dielectric may include any number of dielectric layers deposited using a CVD process, such as ALD. One or more annealing processes may also be used to affect the elemental composition of the gate dielectric.

Method 1900 continues with operation 1910 where a sacrificial structure is formed over the adjacent fins within the gate trench. The sacrificial structure may include any suitable material that can be safely removed at a later time without damaging surrounding materials, such as the gate dielectric. In some examples, the sacrificial structure includes a layer of aluminum oxide. In some examples, the sacrificial structure includes a dielectric liner, such as a thin liner of silicon dioxide over the layer of aluminum oxide. In general, the sacrificial structure is conformally deposited over the transistor structures such that there is space left between the transistor structures within the gate trench, according to some embodiments. Accordingly, the sacrificial structure may be deposited to a final thickness between about 5 nm and about 15 nm using CVD or ALD.

Method 1900 continues with operation 1912 where a mask material is formed over the sacrificial structure within the gate trench. The mask material may be deposited within the gate trench and subsequently polished until a top surface of the mask material is substantially coplanar with a top surface of the spacer structures on either side of the gate trench. In some examples, the mask material is CHM.

Method 1900 continues with operation 1914 where a trench is etched through the mask material between the adjacent fins and an exposed portion of the sacrificial structure within the trench is further etched. The etched trench may extend to a depth through an entire height of the mask material to expose a portion of the sacrificial structure at the bottom of the trench. Furthermore, the trench spans the entire width of the gate trench to also expose sidewall portions of the sacrificial structure at the edges of the gate trench. An RIE process may be used to etch through the mask material while stopping on the sacrificial structure. The trench may be formed through the mask structure anywhere between the adjacent fins along the second direction.

Once the trench has reached the full depth through the mask material, an additional RIE process may be used to remove the exposed portions of the sacrificial structure within the trench. According to some embodiments, the same etch may also be used to remove exposed portions of the gate dielectric within the trench following the removal of the sacrificial structure within the trench. In some examples, a different RIE process is used to remove the gate dielectric. In some examples, one or more isotropic etches are performed to provide more complete removal of the sacrificial structure and/or gate dielectric on the sidewalls within the trench. The isotropic etch may be a wet etching process or may be performed using RIE.

Method 1900 continues with operation 1916 where the mask material is removed and a dielectric structure is formed between the adjacent fins. The mask material may be removed using any suitable isotropic etching process, such as an ashing process. The dielectric structure may include any suitable dielectric material, such as silicon nitride, silicon oxynitride, or silicon oxycarbonitride. The dielectric structure may be deposited using any suitable deposition technique, such as ALD, CVD, PECVD, flowable dielectric, or spin-on dielectric. In some examples, the dielectric structure includes a dielectric liner that includes silicon nitride or silicon carbonitride and a dielectric fill on the dielectric liner that includes silicon dioxide. According to some embodiments, the dielectric structure is deposited within the gate trench and subsequently recessed using any suitable isotropic etching process until the top surface of the sacrificial structure is exposed. Since the dielectric structure fills the space between the sacrificial structure within the gate trench, the dielectric structure is self-aligned directly between the adjacent fins.

Method 1900 continues with operation 1918 where the sacrificial structure is removed and a gate electrode is formed within the gate trench. The sacrificial structure may be removed using any suitable isotropic etching process. The gate electrode may include any number of conductive layers deposited using electroplating, electroless plating, CVD, PECVD, ALD, or PVD, to name a few examples. In some embodiments, the gate electrode includes a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure, the entire structure may be polished or planarized such that the top surface of the gate structure (e.g., top surface of the gate electrode) is substantially coplanar with the top surface of other semiconductor elements, such as the spacer structures that define the gate trench.

Method 1900 continues with operation 1920 where a dielectric plug is formed on a top surface of the dielectric structure. According to some embodiments, a recess is etched through a portion of the gate electrode to expose a top surface of the dielectric structure. The recess may be filled with one or more dielectric materials to form the dielectric plug. A top surface of the dielectric plug may be polished such that it is substantially coplanar with a top surface of the gate electrode or a dielectric layer over the gate electrode. For instance, in some such examples, the top surface of the dielectric plug is within a few angstroms of the top surface of the gate electrode or the dielectric layer over the gate electrode, or perfectly co-planar. The dielectric plug extends across the entire with of the gate trench (e.g., between the spacer structures along the first direction. The dielectric plug may include a single dielectric material, such as silicon nitride, or a dielectric liner and a dielectric fill on the dielectric liner. The dielectric liner may include any suitable high-k dielectric material (e.g., silicon nitride), while the dielectric fill may include any suitable low-k dielectric material (e.g., silicon dioxide).

### Example System

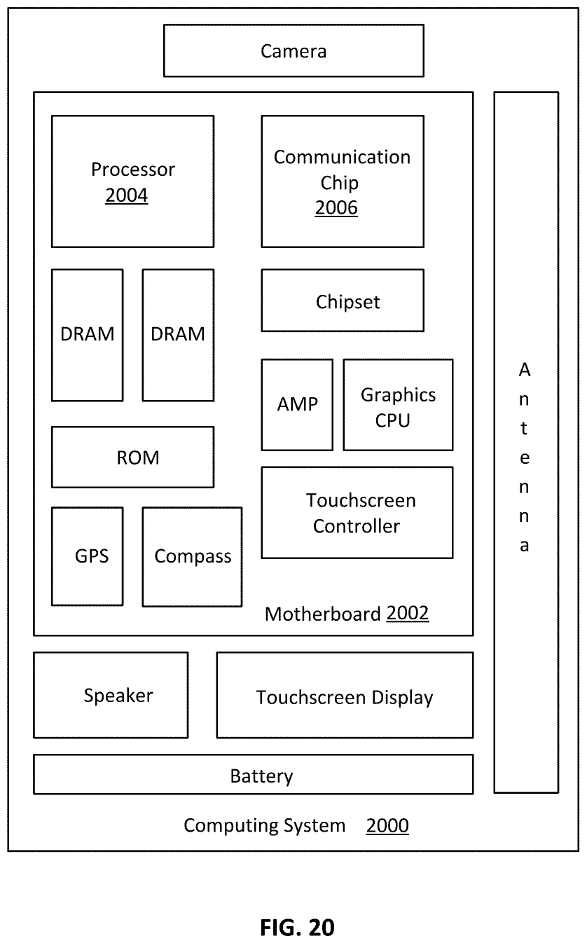

FIG. 20 is an example computing system implemented with one or more of the integrated circuit structures as disclosed herein, in accordance with some embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board (PCB), whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2000 may include one or more integrated circuit structures or devices configured in accordance with an example embodiment, such as a module including an integrated circuit on a substrate, the substrate having semiconductor devices include one or more gate cuts that are self-aligned within the gate trench between adjacent devices. In some embodiments, multiple functions can be integrated into one or more chips (e.g., for instance, note that the communication chip 2006 can be part of or otherwise integrated into the processor 2004).

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. In accordance with some such example embodiments, the integrated circuit die of the communication chip includes one or more semiconductor devices as variously described herein. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2000 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device and a second semiconductor device. The first semiconductor device has a first semiconductor region extending in a first direction from a first source or drain region, and a first gate structure extending in a second direction over the first semiconductor region with the second direction being different than the first direction. The second semiconductor device has a second semiconductor region extending in the first direction from a second source or drain region, and a second gate structure extending in the second direction over the second semiconductor region. Spacer structures are on sidewalls of the first and second gate structures and extend along the second direction with the first and second gate structures, and a gate cut is between the first and second semiconductor devices and separates the first gate structure from the second gate structure along the second direction. A dielectric plug is on the top surface of the gate cut. The gate cut extends along a third direction through at least a portion of an entire height of the first and second gate structures. A top surface of the gate cut is below a top surface of the spacer structures. The dielectric plug also separates the first gate structure from the second gate structure along the second direction.

Example 2 includes the integrated circuit of Example 1, wherein the gate cut comprises silicon and nitrogen.

Example 3 includes the integrated circuit of Example 1 or 2, wherein a first distance between the gate cut and an edge of the first semiconductor region closest to the gate cut along the second direction is substantially the same as a second distance between the gate cut and an edge of the second semiconductor region closest to the gate cut along the second direction.

Example 4 includes the integrated circuit of any one of Examples 1-3, wherein the gate cut does not extend beyond the spacer structures along the first direction.

Example 5 includes the integrated circuit of any one of Examples 1-4, wherein the first gate structure comprises a first gate electrode on a first gate dielectric and the second gate structure comprises a second gate electrode on a second gate dielectric.

Example 6 includes the integrated circuit of Example 5, wherein the first gate electrode contacts a first sidewall of the gate cut and the second gate electrode contacts a second sidewall of the gate cut opposite from the first sidewall, the first and second sidewalls extending along the first direction.

Example 7 includes the integrated circuit of Example 6, wherein third and fourth sidewalls of the gate cut that extend along the second direction contact the spacer structures.

Example 8 includes the integrated circuit of any one of Examples 1-7, wherein the first and second semiconductor regions each comprise a plurality of semiconductor nanoribbons.

Example 9 includes the integrated circuit of Example 8, wherein the plurality of semiconductor nanoribbons comprise germanium, silicon, or a combination thereof.

Example 10 includes the integrated circuit of any one of Examples 1-9, wherein the first semiconductor device is a first forksheet device and the second semiconductor device is a second forksheet device.

Example 11 includes the integrated circuit of any one of Examples 1-10, wherein the gate cut comprises a first section directly contacting a first spacer structure of the spacer structures, a second section directly contacting a second spacer structure of the spacer structures, and a third section between the first and second sections, wherein the third section extends beyond the first and second sections along the second direction.

Example 12 includes the integrated circuit of any one of Examples 1-11, wherein the dielectric plug comprises silicon and oxygen.

Example 13 includes the integrated circuit of any one of Examples 1-12, wherein a top surface of the dielectric plug is substantially coplanar with a top surface of the spacer structures.

Example 14 is a printed circuit board that includes the integrated circuit of any one of Examples 1-13.

Example 15 is an electronic device that includes a chip package having one or more dies. At least one of the one or more dies includes a first semiconductor region extending in a first direction from a first source or drain region, a first gate structure extending in a second direction over the first semiconductor region with the second direction being different than the first direction, a second semiconductor region extending in the first direction from a second source or drain region, a second gate structure extending in the second direction over the second semiconductor region, spacer structures on sidewalls of the first and second gate structures and extending along the second direction with the first and second gate structures, a gate cut between the first and second semiconductor regions and separating the first gate structure from the second gate structure along the second direction, and a dielectric plug on the top surface of the gate cut. The gate cut extends along a third direction through at least a portion of an entire height of the first and second gate structures. A top surface of the gate cut is below a top surface of the spacer structures. The dielectric plug also separates the first gate structure from the second gate structure along the second direction.

Example 16 includes the electronic device of claim 15, wherein the gate cut comprises silicon and nitrogen.

Example 17 includes the electronic device of claim 15 or 16, wherein a first distance between the gate cut and an edge of the first semiconductor region closest to the gate cut along the second direction is substantially the same as a second distance between the gate cut and an edge of the second semiconductor region closest to the gate cut along the second direction.

Example 18 includes the electronic device of any one of Examples 15-17, wherein the gate cut does not extend beyond the spacer structures along the first direction.

Example 19 includes the electronic device of any one of Examples 15-18, wherein the first gate structure comprises a first gate electrode on a first gate dielectric and the second gate structure comprises a second gate electrode on a second gate dielectric.

Example 20 includes the electronic device of claim 19, wherein the first gate electrode contacts a first sidewall of the gate cut and the second gate electrode contacts a second sidewall of the gate cut opposite from the first sidewall, the first and second sidewalls extending along the first direction.

Example 21 includes the electronic device of claim 20, wherein third and fourth sidewalls of the gate cut that extend along the second direction contact the spacer structures.

Example 22 includes the electronic device of any one of Examples 15-21, wherein the first and second semiconductor regions each comprise a plurality of semiconductor nanoribbons.

Example 23 includes the electronic device of claim 22, wherein the plurality of semiconductor nanoribbons comprise germanium, silicon, or a combination thereof.

Example 24 includes the electronic device of any one of Examples 15-23, wherein the first semiconductor region is part of a first forksheet device and the second semiconductor region is part of a second forksheet device.

Example 25 includes the electronic device of any one of Examples 15-24, wherein the gate cut comprises a first section directly contacting a first spacer structure of the spacer structures, a second section directly contacting a second spacer structure of the spacer structures, and a third section between the first and second sections, wherein the third section extends beyond the first and second sections along the second direction.

Example 26 includes the electronic device of any one of Examples 15-25, wherein the dielectric plug comprises silicon and oxygen.

Example 27 includes the electronic device of any one of Examples 15-26, wherein a top surface of the dielectric plug is substantially coplanar with a top surface of the spacer structures.

Example 28 includes the electronic device of any one of Examples 15-27, further comprising a printed circuit board, wherein the chip package is coupled to the printed circuit board.

Example 29 is a method of forming an integrated circuit. The method includes: forming at least two adjacent fins comprising semiconductor material, the fins extending above a substrate and each extending parallel to one another in a first direction; forming a sacrificial gate extending over the semiconductor material in a second direction different from the first direction; forming spacer structures on sidewalls of the sacrificial gate; removing the sacrificial gate; forming a gate dielectric on the semiconductor material of each of the adjacent fins; forming a sacrificial structure over the adjacent fins; forming a masking material over the sacrificial structure between the spacer structures; etching a trench through the masking material between the adjacent fins, such that a portion of the sacrificial structure is exposed at a bottom of the trench; removing a portion of the sacrificial structure within the trench to form a recess; removing the masking material and forming a dielectric fill between the adjacent fins and within the recess; removing the sacrificial structure; forming a gate electrode over the gate dielectric on the semiconductor material of each of the adjacent fins, wherein a portion of the gate electrode extends over a top surface of the dielectric fill; and forming a dielectric plug through the portion of the gate electrode such that the dielectric plug contacts the top surface of the dielectric fill.

Example 30 includes the method of Example 29, wherein forming the sacrificial structure comprises: forming a sacrificial material on the semiconductor material of each of the adjacent fins; and forming a sacrificial liner on the sacrificial material.

Example 31 includes the method of Example 30, wherein the sacrificial material comprises aluminum and oxygen and the sacrificial liner comprises silicon and oxygen.

Example 32 includes the method of any one of Examples 29-31, wherein forming the recess comprises using an isotropic etching process to remove the portion of the sacrificial structure.

Example 33 includes the method of any one of Examples 29-32, wherein forming the gate dielectric comprises forming a high-k dielectric layer.

Example 34 includes the method of any one of Examples 29-33, wherein forming the dielectric plug comprises: forming a cavity through the portion of the gate electrode; forming a dielectric liner within the cavity; and forming a dielectric fill on the dielectric liner.

Example 35 is an integrated circuit that includes a first semiconductor device and a second semiconductor device. The first semiconductor device has a first semiconductor region extending in a first direction from a first source or drain region, and a first gate structure extending in a second direction over the first semiconductor region with the second direction being different than the first direction. The second semiconductor device has a second semiconductor region extending in the first direction from a second source or drain region, and a second gate structure extending in the second direction over the second semiconductor region. Also, spacer structures are on sidewalls of the first and second gate structures and extend along the second direction with the first and second gate structures, and a gate cut is between the first and second semiconductor devices and separating the first gate structure from the second gate structure along the second direction. The gate cut extends along a third direction through at least a portion of an entire height of the first and second gate structures. The gate cut includes a first section directly contacting a first spacer structure of the spacer structures, a second section directly contacting a second spacer structure of the spacer structures, and a third section between the first and second sections. The third section extends beyond the first and second sections along the second direction.

Example 36 includes the integrated circuit of Example 35, wherein the gate cut comprises silicon and nitrogen.

Example 37 includes the integrated circuit of Example 35 or 36, wherein a first distance between the third section of the gate cut and an edge of the first semiconductor region closest to the third section of the gate cut along the second direction is substantially the same as a second distance between the third section of the gate cut and an edge of the second semiconductor region closest to the third section of the gate cut along the second direction.

Example 38 includes the integrated circuit of any one of Examples 35-37, wherein the gate cut does not extend beyond the spacer structures along the first direction.

Example 39 includes the integrated circuit of any one of Examples 35-38, wherein the first gate structure comprises a first gate electrode on a first gate dielectric and the second gate structure comprises a second gate electrode on a second gate dielectric.

Example 40 includes the integrated circuit of Example 39, wherein the first gate electrode contacts a first sidewall of the gate cut and the second gate electrode contacts a second sidewall of the gate cut opposite from the first sidewall, the first and second sidewalls extending along the first direction.

Example 41 includes the integrated circuit of Example 40, wherein third and fourth sidewalls of the gate cut that extend along the second direction contact the spacer structures.

Example 42 includes the integrated circuit of any one of Examples 35-41, wherein the first and second semiconductor regions each comprise a plurality of semiconductor nanoribbons.

Example 43 includes the integrated circuit of Example 42, wherein the plurality of semiconductor nanoribbons comprise germanium, silicon, or a combination thereof.

Example 44 includes the integrated circuit of any one of Examples 35-43, wherein the first semiconductor device is a first forksheet device and the second semiconductor device is a second forksheet device.

Example 45 includes the integrated circuit of any one of Examples 35-44, further comprising a dielectric plug on a top surface of the gate cut, wherein the dielectric plug also separates the first gate structure from the second gate structure along the second direction.

Example 46 includes the integrated circuit of Example 45, wherein the dielectric plug comprises silicon and oxygen.

Example 47 includes the integrated circuit of Example 45 or 46, wherein a top surface of the dielectric plug is substantially coplanar with a top surface of the spacer structures.

Example 48 is a printed circuit board that includes the integrated circuit of any one of Examples 35-47.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region, and a first gate structure extending in a second direction over the first semiconductor region, the second direction being different than the first direction;
a second semiconductor device having a second semiconductor region extending in the first direction from a second source or drain region, and a second gate structure extending in the second direction over the second semiconductor region;
spacer structures on sidewalls of the first and second gate structures and extending along the second direction with the first and second gate structures;
a gate cut between the first and second semiconductor devices and separating the first gate structure from the second gate structure along the second direction, the gate cut extending along a third direction through at least a portion of an entire height of the first and second gate structures, wherein a top surface of the gate cut is below a top surface of the spacer structures; and
a dielectric plug on the top surface of the gate cut, wherein the dielectric plug also separates the first gate structure from the second gate structure along the second direction.

2. The integrated circuit of claim 1, wherein a first distance between the gate cut and an edge of the first semiconductor region closest to the gate cut along the second direction is substantially the same as a second distance between the gate cut and an edge of the second semiconductor region closest to the gate cut along the second direction.

3. The integrated circuit of claim 1, wherein the gate cut does not extend beyond the spacer structures along the first direction.

4. The integrated circuit of claim 1, wherein the first gate structure comprises a first gate electrode on a first gate dielectric and the second gate structure comprises a second gate electrode on a second gate dielectric.

5. The integrated circuit of claim 4, wherein the first gate electrode contacts a first sidewall of the gate cut and the second gate electrode contacts a second sidewall of the gate cut opposite from the first sidewall, the first and second sidewalls extending along the first direction.

6. The integrated circuit of claim 5, wherein third and fourth sidewalls of the gate cut that extend along the second direction contact the spacer structures.

7. The integrated circuit of claim 1, wherein the gate cut comprises a first section directly contacting a first spacer structure of the spacer structures, a second section directly contacting a second spacer structure of the spacer structures, and a third section between the first and second sections, wherein the third section extends beyond the first and second sections along the second direction.

8. A printed circuit board comprising the integrated circuit of claim 1.

9. An electronic device, comprising:
a chip package comprising one or more dies, at least one of the one or more dies comprising
a first semiconductor region extending in a first direction from a first source or drain region;
a first gate structure extending in a second direction over the first semiconductor region, the second direction being different than the first direction;
a second semiconductor region extending in the first direction from a second source or drain region;
a second gate structure extending in the second direction over the second semiconductor region;
spacer structures on sidewalls of the first and second gate structures and extending along the second direction with the first and second gate structures;
a gate cut between the first and second semiconductor regions and separating the first gate structure from the second gate structure along the second direction, the gate cut extending along a third direction through at least a portion of an entire height of the first and second gate structures, wherein a top surface of the gate cut is below a top surface of the spacer structures; and
a dielectric plug on the top surface of the gate cut, wherein the dielectric plug also separates the first gate structure from the second gate structure along the second direction.

10. The electronic device of claim 9, wherein a first distance between the gate cut and an edge of the first semiconductor region closest to the gate cut along the second direction is substantially the same as a second distance between the gate cut and an edge of the second semiconductor region closest to the gate cut along the second direction.

11. The electronic device of claim 9, wherein the first gate structure comprises a first gate electrode on a first gate dielectric and the second gate structure comprises a second gate electrode on a second gate dielectric.

12. The electronic device of claim 11, wherein the first gate electrode contacts a first sidewall of the gate cut and the second gate electrode contacts a second sidewall of the gate cut opposite from the first sidewall, the first and second sidewalls extending along the first direction.

13. The electronic device of claim 12, wherein third and fourth sidewalls of the gate cut that extend along the second direction contact the spacer structures.

14. The electronic device of claim 9, wherein the gate cut comprises a first section directly contacting a first spacer structure of the spacer structures, a second section directly contacting a second spacer structure of the spacer structures, and a third section between the first and second sections, wherein the third section extends beyond the first and second sections along the second direction.

15. An integrated circuit comprising:
a first semiconductor device having a first semiconductor region extending in a first direction from a first source or drain region, and a first gate structure extending in a second direction over the first semiconductor region, the second direction being different than the first direction;
a second semiconductor device having a second semiconductor region extending in the first direction from a second source or drain region, and a second gate structure extending in the second direction over the second semiconductor region;
spacer structures on sidewalls of the first and second gate structures and extending along the second direction with the first and second gate structures; and
a gate cut between the first and second semiconductor devices and separating the first gate structure from the second gate structure along the second direction, the gate cut extending along a third direction through at least a portion of an entire height of the first and second gate structures, the gate cut comprising
a first section directly contacting a first spacer structure of the spacer structures,
a second section directly contacting a second spacer structure of the spacer structures, and
a third section between the first and second sections, wherein the third section extends beyond the first and second sections along the second direction.

16. The integrated circuit of claim 15, wherein a first distance between the third section of the gate cut and an edge of the first semiconductor region closest to the third section of the gate cut along the second direction is substantially the same as a second distance between the third section of the gate cut and an edge of the second semiconductor region closest to the third section of the gate cut along the second direction.

17. The integrated circuit of claim 15, wherein the first gate structure comprises a first gate electrode on a first gate dielectric and the second gate structure comprises a second gate electrode on a second gate dielectric.

18. The integrated circuit of claim 17, wherein the first gate electrode contacts a first sidewall of the gate cut and the second gate electrode contacts a second sidewall of the gate cut opposite from the first sidewall, the first and second sidewalls extending along the first direction.

19. The integrated circuit of claim 18, wherein third and fourth sidewalls of the gate cut that extend along the second direction contact the spacer structures.

20. The integrated circuit of claim 15, further comprising a dielectric plug on a top surface of the gate cut, wherein the dielectric plug also separates the first gate structure from the second gate structure along the second direction.
